(19) United States
(12) Patent Application Publication
(10) Pub. No.: US 2012/0280243 A1
(43) Pub. Date: Nov. 8, 2012

(54) SEMICONDUCTOR SUBSTRATE AND FABRICATING METHOD THEREOF

(75) Inventors: Chong-Ming Lee, Taipei (TW); Andrew Eng Jia Lee, Taipei (TW)

(73) Assignee: NANOCRYSTAL ASIA INC., Taipei (TW)

(21) Appl. No.: 13/279,337

(22) Filed: Oct. 24, 2011

Related U.S. Application Data
(60) Provisional application No. 61/483,066, filed on May 6, 2011.

(51) Int. Cl. H01L 29/02; H01L 21/20

(52) U.S. Cl. 257/76; 438/478; 257/E21.09; 257/E29.002

(57) ABSTRACT

A fabricating method of a semiconductor substrate is provided. A patterned mask layer is formed on a substrate base. The patterned mask layer includes a plurality of apertures, and each aperture exposes a portion of the substrate base. A plurality of nano-pillars is formed on the substrate base, wherein each nano-pillar is grown on the portion of the substrate base exposed by each aperture. An insulating layer is formed on a sidewall of each nano-pillar. An epitaxial lateral overgrowth process is performed on a top portion of each nano-pillar, so as to form a semiconductor layer on the nano-pillars, wherein the semiconductor layer is exposed by a plurality of gaps disposed between the nano-pillars.

### CROSS-REFERENCE TO RELATED APPLICATION

This application claims the priority benefits of U.S. provisional application Ser. No. 61/483,066, filed on May 6, 2011. The entirety of the above-mentioned patent applications is hereby incorporated by reference herein and made a part of this specification.

### BACKGROUND OF THE INVENTION

1. Field of the Invention

The invention relates to a substrate and a fabricating method thereof More particularly, the invention relates to a semiconductor substrate and a fabricating method thereof

2. Description of Related Art

A group III-V nitride material is a semiconductor having a wide band gap. For example, gallium nitride materials have been adopted for fabricating short wavelength light emitting diodes (LEDs), laser diodes, high power electronic devices, and so on for the last couple of years. Having a wide optical penetration band, sapphires have superior light transmittance from near ultraviolet (190 nm) to middle infrared, and include characteristics such as high sound velocity, high temperature tolerance, corrosion resistance, high hardness, high melting point, and low electric conductivity. Accordingly, sapphires are usually applied as substrate bases for growing gallium nitride (GaN) blocks used to fabricate electronic devices.

However, sapphires and semiconductor materials such as GaN have mismatched lattice constants and a large difference between thermal expansion coefficients, so that more lattice defects, for example, dislocation, stacking fault, and the like are generated during the process of growing GaN blocks on the surfaces of sapphire substrate base. Accordingly, the GaN blocks may easily break due to the stress difference generated from the high temperature environment required by the process, thereby affect the optical property thereof.

In addition, since sapphires have high hardness, the hardness of sapphires after epitaxial growth is only next to that of natural diamonds. Moreover, the crystal grains have a small gap therebetween (about 2 mil, 1 mil= 1/1000 inch) and need to be cut with a diamond knife to separate the crystal grains through grinding. Since the crystal grains are fragile, the crystal grains may easily collapse or crack during the cutting process.

One conventional solution is to form a buffer layer between the sapphire substrate base and the GaN block to reduce the stress difference between the sapphire substrate base and the GaN block, thereby decreasing the defect density of the GaN block. Generally, the buffer layer can be constituted by an amorphous GaN structure. The buffer layer indeed improves the cracking caused by the stress generated from high temperature; however, since the amorphous GaN structure has defects on the surface thereof when grown on the sapphire substrate base as the buffer layer, the defect density of the GaN block cannot be decreased effectively. In other words, when grown on a bufferlayer with defects, the GaN block breaks easily due to the defects. Further, since the amorphous GaN structure is grown above the sapphire substrate base in a planar manner, the amorphous GaN structure may break or collapse in the wafer-dicing process due to the stress difference between the sapphire and the GaN.

Therefore, researches now focus on how to prevent the semiconductor layer formed from having lattice defects caused by mismatched lattice constants between the substrate base and the semiconductor layer.

### SUMMARY OF THE INVENTION

The invention is directed to a fabricating method of a semiconductor substrate for decreasing the defect density of the semiconductor substrate and the stress difference between the semiconductor substrate and a substrate base.

The invention is further directed to a semiconductor substrate having low defect density.

The invention is directed to a fabricating method of a semiconductor substrate. A patterned mask layer is formed on a substrate base. The patterned mask layer includes a plurality of apertures each exposing a portion of the substrate base. A plurality of nano-pillars is formed on the substrate base. Each of the nano-pillars is grown on the portion of the substrate base exposed by each of the apertures. An insulation layer is formed on a sidewall of each of the nano-pillars. An epitaxial lateral overgrowth process is performed on a top portion of each of the nano-pillars to form a semiconductor layer on the nano-pillars. The semiconductor layer is exposed by a plurality of gaps disposed between the nano-pillars.

The invention is directed to a semiconductor substrate including a substrate base, a patterned mask layer, a plurality of nano-pillars, an insulation layer, and a semiconductor layer. The patterned mask layer is disposed on the substrate base and includes a plurality of apertures each exposing a portion of the substrate base. Each nano-pillar is located on the portion of the substrate base exposed by each of the apertures, where each of the nano-pillars has a top portion and a sidewall. The insulation layer covers the sidewall of each of the nano-pillars. The semiconductor layer is disposed on the top portions of the nano-pillars. The semiconductor layer is exposed by a plurality of gaps disposed between the nano-pillars.

According to an embodiment of the invention, each of the apertures has a size ranging from 20 nanometer (nm) to 2000 nm.

According to an embodiment of the invention, each of the gaps has a size ranging from 20 nm to 2000 nm.

According to an embodiment of the invention, a material of the nano-pillars is the same as a material of the semiconductor layer.

According to an embodiment of the invention, a material of the semiconductor layer includes a group-III metal nitride.

According to an embodiment of the invention, a material of the semiconductor layer includes gallium nitride (GaN), aluminum gallium nitride (AlGaN), aluminum nitride (AlN), indium gallium nitride (InGaN), or a combination thereof.

According to an embodiment of the invention, a method of forming the insulation layer on the sidewall of each of the nano-pillars includes the following. An insulation material layer is formed on each of the nano-pillars. The insulation material layer covers the sidewall and the top portion of each of the nano-pillars. The insulation material layer on the top portion of each of the nano-pillars is removed so as to expose the top portion of each nano-pillar.

According to an embodiment of the invention, a method of forming the insulation material layer includes a plasma-enhanced chemical vapor deposition (PECVD), an inductively coupled plasma chemical vapor deposition (ICP-CVD), or other deposition methods.

According to an embodiment of the invention, a method of removing the insulation material layer on the top portion of each of the nano-pillars includes a dry etching process.

According to an embodiment of the invention, a material of the insulation layer includes silicon nitride or silicon dioxide.

According to an embodiment of the invention, a method of forming the semiconductor layer includes the following. A crystal is formed on the top portion of each of the nano-pillars through the epitaxial lateral overgrowth process. The epitaxial lateral overgrowth process is then continued for the crystals on the top portions of the nano-pillars to coalesce one another laterally.

According to an embodiment of the invention, a thermal annealing process is further performed to the semiconductor layer.

According to an embodiment of the invention, a separation process is further performed to separate the semiconductor layer and the substrate base after the semiconductor layer is formed.

According to an embodiment of the invention, the separation process includes truncating the nano-pillars.

In light of the foregoing, a plurality of nano-pillars each having the sidewall covered with the insulation layer is formed on the substrate base in the invention. The semiconductor is then formed on the nano-pillars through the epitaxial lateral overgrowth process. Since the semiconductor layer is formed on the nano-pillars by a coalescence through the epitaxial lateral overgrowth process, the stress generated in the semiconductor layer during the epitaxial lateral overgrowth process can be reduced as being released through the gaps between the nano-pillars. The semiconductor layer thus has a surface with low defect density. Accordingly, the light emitting efficiency of the light emitting device can be enhanced when applying the semiconductor layer in the light emitting device.

In order to make the aforementioned and other features and advantages of the invention more comprehensible, several embodiments accompanied with figures are described in detail below.

### BRIEF DESCRIPTION OF THE DRAWINGS

The accompanying drawings are included to provide further understanding, and are incorporated in and constitute a part of this specification. The drawings illustrate embodiments and, together with the description, serve to explain the principles of the invention.

FIG. 1 is a flowchart illustrating a fabricating method of a semiconductor substrate according to one embodiment of the invention.

FIGS. 2A to 2H are schematic cross-sectional views showing a flowchart of fabricating a semiconductor substrate according to one embodiment of the invention.

### DESCRIPTION OF EMBODIMENTS

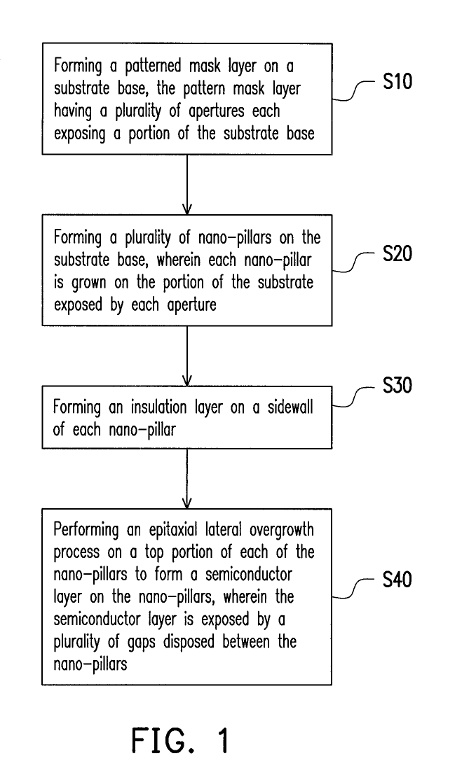

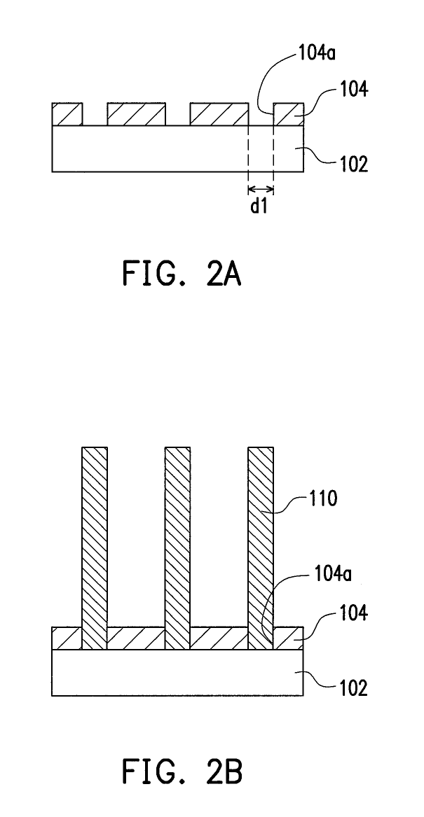

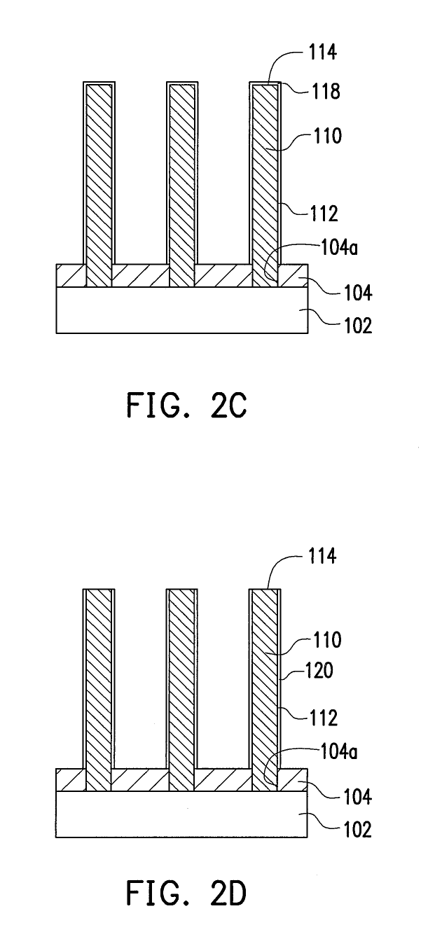

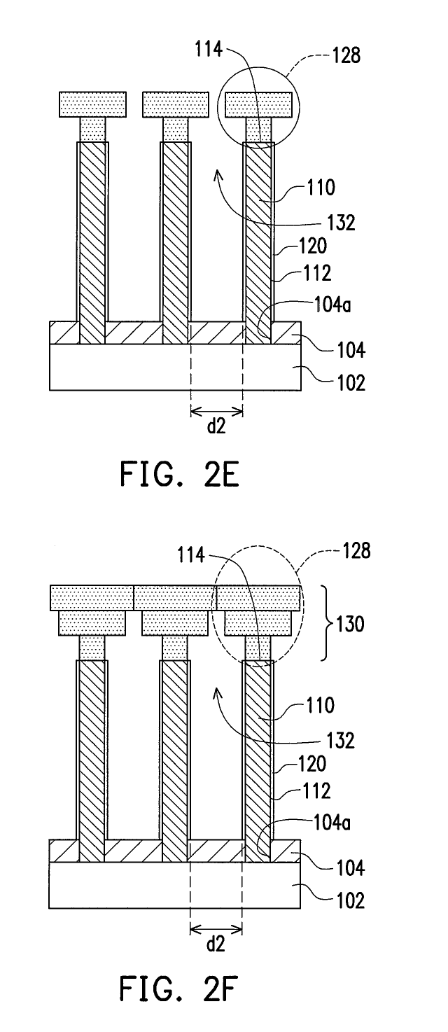

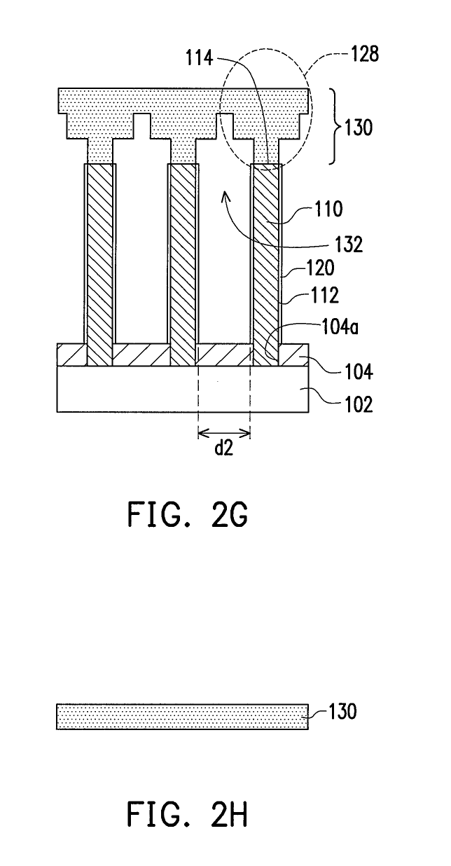

FIG. 1 is a flowchart illustrating a fabricating method of a semiconductor substrate according to one embodiment of the invention. FIGS. 2A to 2H are schematic cross-sectional views showing a flowchart of fabricating a semiconductor substrate according to one embodiment of the invention. Referring to FIG. 1 and FIGS. 2A to 2B simultaneously, firstly, step S10 is performed to form a patterned mask layer 104 on a substrate base 102. The patterned mask layer 104 includes a plurality of apertures 104a each exposing a portion of the substrate base 102. In details, in the present embodiment, as shown in FIG. 2A, the substrate base 102 is first provided. In the present embodiment, a material of the substrate base 102 includes silicon, silicon carbide, sapphire, aluminum oxide, group III-V semiconductor compound (i.e. gallium nitride (GaN), aluminum nitride (AlN), gallium arsenide (GaAs), gallium phosphide (GaP), indium phosphide (InP)) or other epitaxial material.

Thereafter, the patterned mask layer 104 is formed on the substrate base 102. The patterned mask layer 104 includes the apertures 104a each exposing a portion of the substrate base 102. The apertures 104a are arranged in an array, for example, and the apertures 104a have a certain gap therebetween. In the present embodiment, the apertures 104a have a hexagonal shape, triangular shape, square shape, rectangular shape, elliptical shape, or circular shape, for instance. The apertures 104a have a size dl ranging from 20 nanometer (nm) to 2000 nm, for instance. The apertures 104a have a gap ranging from 20 nm to 2000 nm, for instance. A material of the patterned mask layer 104 includes, for instance, a dielectric material such as silicon nitride, silicon dioxide, silicon oxynitride, fluorinated silicon oxide, silicon oxycarbide, hafnia, hafnium silicate, hafnium silicon oxynitride, zirconium oxide, aluminum oxide, and so on. The patterned mask layer 104 has a thickness ranging from 10 Å to 5000 Å, for example.

Referring to FIGS. 1 and 2B simultaneously, step S20 is then performed to form a plurality of nano-pillars 110 on the substrate base 102. The nano-pillars 110 are each grown on the portion of the substrate base 102 exposed by each of the apertures 104a. In the present embodiment, each of the nano-pillars 110 includes a plurality of nano-wires. In other words, the nano-wires grown on the substrate base 102 which is exposed by the apertures 104a then aggregate to form the nano-pillars 110. The nano-pillars 110 are separated from one another and have a gap ranging from 20 nm to 2000 nm therebetween, for instance. A method of growing the nano-wires includes a suitable method, for example, a metal-organic chemical vapor deposition method (MOCVD), molecular beam epitaxy (MBE), gas source molecular beam epitaxy (GSMBE), metal-organic molecular beam epitaxy (MOMBE), atomic layer epitaxy (ALE), hydride vapor phase epitaxy (HVPE), and so on. A material of the nano-wires is, for example, a semiconductor including a group III-V compound semiconductor or a group II-VI compound semiconductor such as gallium nitride (GaN), aluminum nitride (AlN), indium nitride (InN), indium gallium nitride (InGaN), aluminum gallium nitride (AlGaN), or aluminum indium gallium nitride (AlInGaN), and is favorably GaN.

In details, the substrate base 102 shown in FIG. 2A is placed into a reaction furnace, such that a saturated vapor of a reaction source is carried by a carrier gas into the reaction furnace to mix with other reacting gases. Accordingly, a chemical reaction is caused between the mixed gas undergoes and the surface of the heated substrate base 102, and therefore nano-wires are grown selectively on the portion of the substrate base 102 exposed by the apertures 104a. Generally, hydrogen gas is adopted as the carrier gas; however, nitrogen gas is used under certain circumstances (i.e. growing InGaN). The reaction source can be a metal-organic reaction source or a hydride gas reaction source. The metal-organic reaction source includes trimethylgallium (TMGa), triethylgallium (TEGa), trimethylaluminum (TMAl), trimethylindium (TMIn), bis(cyclopentadienyl)magnesium (Cp2Mg), diisopropyl telluride (DIPTe) and the like. The hydride gas reaction source includes arsenic hydride (AsH₃), phosphine (PH₃), ammonia (NH₃), disilane (Si₂H₆), and so on. In the present embodiment, the nano-wires formed with GaN are used as an example. Thus, the reaction furnace is, for example, a MOCVD reaction furnace, the reaction source gas includes, for example, TMGa and NH₃, and the carrier gas is, for instance, hydrogen gas.

It should be noted that since the nano-pillars 110 are grown on the portion of the substrate base 102 exposed by the apertures 104a of the patterned mask layer 104, the patterned mask layer 104 can be adopted as a source of lateral support for the nano-pillars 110 in the growing process of the nano-pillars 110 so as to enhance the stability of the nano-pillars 110.

Referring to FIGS. 1, 2C, and 2D simultaneously, afterwards, step S30 is carried out to form an insulation layer 120 on a sidewall 112 of each of the nano-pillars 110. As depicted in FIG. 2C, in this step, an insulation material layer 118 is first formed on a surface of each nano-pillar 110 using a plasma-enhanced chemical vapor deposition (PECVD), for example. The insulation material layer 118 covers the sidewall 112 and a top portion 114 of each of the nano-pillars 110. As shown in FIG. 2D, the insulation material layer 118 on the top portion 114 of each of the nano-pillars 110 is then removed to expose the top portion 114 of each nano-pillar 110. The insulation material layer 118 on the top portion 114 of each of the nano-pillars 110 can be removed by a dry etching process. Here, a material of the insulation layer 120 includes silicon nitride or silicon dioxide. Moreover, the insulation layer 120 has a thickness ranging from 10 Angstroms (Å) to 2000 Å, for example.

Referring to FIG. 1 and FIGS. 2E to 2F simultaneously, then, step S40 is carried out to perform an epitaxial lateral overgrowth process to the top portion 114 of each of the nano-pillars 110, so that a semiconductor layer 130 is formed on the nano-pillars 110. Here, the semiconductor layer 130 is exposed by a plurality of gaps 132 between the nano-pillars 110. In the present embodiment, the epitaxial lateral overgrowth process adopts, for example, a MOCVD to perform the coalescence and layer development of the semiconductor layer 130. In details, in the epitaxial lateral overgrowth process, for example, a crystal 128 is first formed on the top portion 114 of each nano-pillar 110. The crystals 128 on the top portions 114 of the nano-pillars 110 then laterally coalesce one another to form the semiconductor layer 130. The process aforementioned is substantially the continuing process illustrated in FIGS. 2E to 2F. That is, the crystals 128 grow vertically and laterally on the top portions 114 of the nano-pillars 110, so that the height and width thereof increase simultaneously. When the width of each crystal 128 increases to a certain level, the adjacent crystals 128 coalesce one another laterally to form the semiconductor layer 130. It should be noted that since the sidewall 112 of each nano-pillar 110 is covered with the insulation layer 120, the crystals 128 obtain growth selectivity when growing on the nano-pillars 110, so that the epitaxial lateral overgrowth process is performed on the top portions 114 of the nano-pillars 110. The lateral growth of the sidewalls of the nano-pillars 110 can therefore be prevented to maintain a plurality of gaps 132 between the nano-pillars 110 so as to ensure the stress generated from the growing process of the semiconductor layer 130 can be released through the gaps 132 between the nano-pillars 110. In the present embodiment, the gaps 132 between the nano-pillars 110 have a size d2 ranging from 20 nm to 2000 nm, for example.

In the present embodiment, an additive having a concentration gradient can be added to control the width of the crystals 128 growing on the top portions 114 of the nano-pillars 110, such that the width of the crystals 128 is increased gradually. Accordingly, when the width of the crystals 128 increases to a certain level, the adjacent crystals 128 connect to one another and are coalesced to form a flat and extending semiconductor layer 130 on the top portions 114 of the nano-pillars 110. Particularly, the nano-pillars 110 provide a more stable support to the crystals 128 with gradually increasing width to prevent the nano-pillars 110 from bending or breaking due to the weight. The additive can be trimethylgallium (TMGa), triethylgallium (TEGa), trimethylindium (TMIn), triethylindium (TEIn), trimethylaluminum (TMAl), or other suitable additive. The semiconductor layer 130 has a thickness ranging from 2 μm to 20 μm, for example. In the present embodiment, a material of the semiconductor layer 130 is, for instance, a group III metal nitride including GaN, AlGaN, AlN, InGaN, or a combination thereof. Here, the semiconductor layer 130 is favorably GaN. It should be illustrated that since the crystals with gradually increasing width and the gaps between the nano-wires are conducive to release the stress generated by the substrate base, the semiconductor layer can provide a stable structure when adopted as the substrate base for forming the semiconductor blocks, so as to allow the formation of thicker blocks thereon.

Referring to FIG. 2G, in the present embodiment, after the crystals 128 are coalesced into the semiconductor layer 130, a thermal annealing process is performed to the semiconductor layer 130. In details, when the crystals 128 are coalesced into the semiconductor layer 130, the coalescing sites of the crystals 128 may form boundaries of crystal grains as shown in FIG. 2F. At this time, the boundaries of crystal grains can be eliminated through the thermal annealing process to form the semiconductor layer 130 depicted in FIG. 2G. Moreover, the thermal annealing process also planarizes the semiconductor layer 130, so that the surface of the semiconductor layer 130 is flat and defect-free, suitable for growing crystals thereon subsequently. In addition, the thermal annealing process also enhances the stability of the nano-pillars 110 to prevent the collapse thereof. Here, the thermal annealing process applies a gas with high purity and low price, for example, argon gas, hydrogen gas, nitrogen gas, or so on. The thermal annealing process has a temperature ranging from 500° C. to 1300° C., for instance.

The semiconductor substrate formed using the method aforementioned is shown in FIG. 2G. The semiconductor substrate includes the substrate base 102, the patterned mask layer 104, the nano-pillars 110, the insulation layer 120, and the semiconductor layer 130. The patterned mask layer 104 is disposed on the substrate base 102 and includes the apertures 104a each exposing a portion of the substrate base 102. Each nano-pillar 110 is located on the portion of the substrate base 102 exposed by each of the apertures 104a, where each of the nano-pillars 110 has the top portion 114 and the sidewall 112. The insulation layer 120 covers the sidewall 112 of each of the nano-pillars 110. The semiconductor layer 130 is disposed on the top portions 114 of the nano-pillars 110. The semiconductor layer 130 is exposed by the gaps 132 disposed between the nano-pillars 110.

After the semiconductor layer 130 is formed, the separation process can then be performed to separate the semiconductor layer 130 and the substrate base 102 as shown in FIG. 2H. In the present embodiment, a method of separating the semiconductor layer 130 and the substrate base 102 includes the following. For example, the thickness of the semiconductor layer 130 is increased to generate a large stress to the nano-pillars 110, such that the nano-pillars 110 break themselves. Or, for example, the nano-pillars 110 are etched using an etching solution. Here, the etching solution is, for example, a potassium hydroxide solution or a solution mixed with nitric acid and hydrofluoric acid. After the separation, the semiconductor 130 can be applied in the fabrication of a semiconductor light emitting device. In particular, since the nano-pillars 110 are more fragile comparing to the substrate base 102, as the thickness of the semiconductor block subsequently formed on the semiconductor layer 130 increases gradually, the substrate base 102 can be removed easily by truncating the nano-pillars 110 without damaging the semiconductor block.

In summary, in the invention, the nano-pillars are formed on the substrate base, the semiconductor layer is formed on the top portions of the nano-pillars through the epitaxial lateral overgrowth process after the sidewall of each nano-pillar is covered with the insulation layer. Since the semiconductor layer is formed by coalescing the nano-pillars through the epitaxial lateral overgrowth process, the gaps between the nano-pillars can release the stress generated from the cooling process of the semiconductor layer performed during the epitaxial overgrowth. As a consequence, the quality of the semiconductor layer can be enhanced and the probability of the semiconductor layer breakage can be decreased. In other words, the invention utilizes the gaps between the nano-pillars as a buffer to prevent the breakage or the defect formation of the semiconductor layer caused by stress resulted in the fabricating process. Additionally, when the semiconductor layer is applied in the fabrication of light emitting devices, the gaps between adjacent nano-pillars then provide different refraction indexes in the light exiting path. As a result, the total reflection of the incident light can be reduced significantly and the diffraction angle of the incident light can be increased, so as to enhance the light extraction efficiency of the light emitting device.

On the other hand, the sidewalls of the nano-pillars in the invention are covered with the insulation layer, such that the semiconductor epitaxial layer has growth selectivity when growing on the nano-pillars and the epitaxial lateral overgrowth process is performed on the top portions of the nano-pillars. The lateral growth of the sidewalls of the nano-pillars can therefore be prevented to maintain the gaps between the nano-pillars so as to ensure the stress generated from the growing process of the semiconductor layer can be released from the gaps between the nano-pillars. Furthermore, the insulation layers on the sidewalls of the nano-pillars prevent the nano-pillars from being corroded in the growing process. Also, when adopting the substrate base with the nano-pillars as the substrate base for growing the semiconductor layer, the contact area between the semiconductor material and the substrate base is reduced and the stress between the substrate base and the semiconductor layer is decreased, so as to avoid the breakage of the semiconductor crystal. Moreover, since the contact area between the semiconductor layer and the nano-pillars is extremely small, a faster and easier method can be applied for separating the two (i.e. the breaking of the nano-pillars due to the large stress generated when the semiconductor reaches a certain thickness, or the etching of the nano-pillars using the etching solution). As a consequence, the complexity for separating the substrate base and the semiconductor layer with the laser lift-off process can be prevented and the fabrication cost can be reduced. Therefore, the semiconductor layer obtained is not damaged by laser or other processes, and the semiconductor substrate fabricated in the invention has better quality comparing to conventional semiconductor substrates. When applied in the fabrication of light emitting device, this semiconductor substrate also enhances the light emitting efficiency of the light emitting device.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A fabricating method of a semiconductor substrate, the fabricating method comprising:
forming a patterned mask layer on a substrate base, the patterned mask layer comprising a plurality of apertures each exposing a portion of the substrate base;
forming a plurality of nano-pillars on the substrate base, wherein each of the nano-pillars is grown on the portion of the substrate base exposed by each of the apertures;
forming an insulation layer on a sidewall of each of the nano-pillars; and
performing an epitaxial lateral overgrowth process on a top portion of each of the nano-pillars to form a semiconductor layer on the nano-pillars, wherein the semiconductor layer is exposed by a plurality of gaps disposed between the nano-pillars.

2. The fabricating method of the semiconductor substrate as claimed in claim 1, wherein a method of forming the insulation layer on the sidewall of each of the nano-pillars comprises:
forming an insulation material layer on each of the nano-pillars, the insulation material layer covering the sidewall and the top portion of each of the nano-pillars; and
removing the insulation material layer on the top portion of each of the nano-pillars so as to expose the top portion of each nano-pillar.

3. The fabricating method of the semiconductor substrate as claimed in claim 2, wherein a method of forming the insulation material layer comprises a plasma-enhanced chemical vapor deposition or an inductively coupled plasma chemical vapor deposition.

4. The fabricating method of the semiconductor substrate as claimed in claim 2, wherein a method of removing the insulation material layer on the top portion of each of the nano-pillars comprises a dry etching process.

5. The fabricating method of the semiconductor substrate as claimed in claim 1, wherein a material of the insulation layer comprises silicon nitride or silicon dioxide.

6. The fabricating method of the semiconductor substrate as claimed in claim 1, wherein a method of forming the semiconductor layer comprises:
forming a crystal on the top portion of each of the nano-pillars through the epitaxial lateral overgrowth process; and
continuing the epitaxial lateral overgrowth process for the crystals on the top portions of the nano-pillars to coalesce one another laterally.

7. The fabricating method of the semiconductor substrate as claimed in claim 1, further comprising performing a thermal annealing process to the semiconductor layer.

8. The fabricating method of the semiconductor substrate as claimed in claim 1, wherein a separation process is further performed to separate the semiconductor layer and the substrate base after the semiconductor layer is formed.

9. The fabricating method of the semiconductor substrate as claimed in claim 8, wherein the separation process comprises truncating the nano-pillars.

10. The fabricating method of the semiconductor substrate as claimed in claim 1, wherein a material of the nano-pillars is the same as a material of the semiconductor layer.

11. The fabricating method of the semiconductor substrate as claimed in claim 1, wherein a material of the semiconductor layer comprises a group-III metal nitride.

12. The fabricating method of the semiconductor substrate as claimed in claim 1, wherein a material of the semiconductor layer comprises gallium nitride (GaN), aluminum gallium nitride (AlGaN), aluminum nitride (AlN), indium gallium nitride (InGaN), or a combination thereof.

13. The fabricating method of the semiconductor substrate as claimed in claim 1, wherein each of the apertures has a size ranging from 20 nanometer (nm) to 2000 nm.

14. The fabricating method of the semiconductor substrate as claimed in claim 1, wherein each of the gaps has a size ranging from 20 nm to 2000 nm.

15. A semiconductor substrate, comprising:
a substrate base;
a patterned mask layer, disposed on the substrate base and comprising a plurality of apertures each exposing a portion of the substrate base;
a plurality of nano-pillars, each nano-pillar located on the portion of the substrate base exposed by each of the apertures, wherein each of the nano-pillars comprises a top portion and a sidewall;
an insulation layer, covering the sidewall of each of the nano-pillars; and
a semiconductor layer, disposed on the top portions of the nano-pillars, wherein the semiconductor layer is exposed by a plurality of gaps disposed between the nano-pillars.

16. The semiconductor substrate as claimed in claim 15, wherein each of the apertures has a size ranging from 20 nm to 2000 nm.

17. The semiconductor substrate as claimed in claim 15, wherein each of the gaps has a size ranging from 20 nm to 2000 nm.

18. The semiconductor substrate as claimed in claim 15, wherein a material of the nano-pillars is the same as a material of the semiconductor layer.

19. The semiconductor substrate as claimed in claim 15, wherein a material of the semiconductor layer comprises a group-III metal nitride.

20. The semiconductor substrate as claimed in claim 15, wherein a material of the semiconductor layer comprises GaN, AlGaN, AN, InGaN, or a combination thereof
